(19) United States
(12) Patent Application Publication
(10) Pub. No.: US 2025/0373228 A1
(43) Pub. Date: Dec. 4, 2025

(54) ACOUSTIC WAVE DEVICE, FILTER, AND MULTIPLEXER

(71) Applicant: TAIYO YUDEN CO., LTD., Tokyo (JP)

(72) Inventor: Shodai HARAI, Tokyo (JP)

(73) Assignee: TAIYO YUDEN CO., LTD., Tokyo (JP)

(21) Appl. No.: 19/184,771

(22) Filed: Apr. 21, 2025

(30) Foreign Application Priority Data
May 30, 2024 (JP) 2024-088238

(51) Int. Cl. H03H 9/145; H03H 9/02; H03H 9/64

(52) U.S. Cl. CPC H03H 9/14517; H03H 9/02992; H03H 9/6483

(57) ABSTRACT

An acoustic wave device includes a piezoelectric layer, and a pair of interdigital electrodes provided on the piezoelectric layer. Each of the pair of interdigital electrodes has electrode fingers and a bus bar to which the electrode fingers are connected. An intersection region where the electrode fingers intersect each other includes an edge region, a central region, and an intermediate region located between the edge region and the central region. When a weight per unit length in the longitudinal direction of a single-layer or multilayer film including a metal layer of at least one of the electrode fingers provided on the piezoelectric layer is a first weight in the central region, a second weight in the intermediate region, and a third weight in the edge region, the second weight is larger than the first weight and the third weight is smaller than the first weight.

### CROSS-REFERENCE TO RELATED APPLICATION

This application is based upon and claims the benefits of priorities of the prior Japanese Patent Application No. 2024-088238, filed on May 30, 2024, entire contents of which are incorporated herein by reference.

### FIELD

A certain aspect of the present embodiments relates to an acoustic wave device, a filter, and a multiplexer.

### BACKGROUND

An acoustic wave device is used in a high-frequency communication system represented by a portable telephone. There has been known an acoustic wave device provided with a pair of interdigital electrodes having a plurality of electrode fingers and a bus bar to which the plurality of electrode fingers are connected. It is known that the sound velocity of an acoustic wave in an edge region located at an edge in the longitudinal direction of an electrode finger in an intersection region where a plurality of electrode fingers of a pair of interdigital electrodes intersect is made different from the sound velocity of an acoustic wave in a central region located inside the edge region (for example, Patent Document 1: Japanese National Publication of International Patent Application No. 2013-518455). It is known that a piston mode is realized and the spurious is suppressed by making the sound velocity of the acoustic wave in the edge region slower than the sound velocity of the acoustic wave in the central region (for example, Patent Document 2: Japanese Patent Application Publication No. 2016-136712, and Patent Document 3: Japanese Patent Application Publication No. 2019-125856).

### SUMMARY

According to an aspect of the present disclosure, there is provided an acoustic wave device including: a piezoelectric layer; and a pair of interdigital electrodes provided on the piezoelectric layer, each of the pair of interdigital electrodes having a plurality of electrode fingers and a bus bar to which the plurality of electrode fingers are connected, an intersection region where the plurality of electrode fingers intersect each other including an edge region located at an edge in a longitudinal direction of the plurality of electrode fingers, a central region located inside the edge region, and an intermediate region located between the edge region and the central region; wherein, when a weight per unit length in the longitudinal direction of a single-layer or multilayer film including a metal layer of at least one of the plurality of electrode fingers provided on the piezoelectric layer at a location where the at least one of the plurality of electrode fingers is located is a first weight in the central region, a second weight in the intermediate region, and a third weight in the edge region, the second weight is larger than the first weight and the third weight is smaller than the first weight.

According to a second aspect of the present disclosure, there is provided an acoustic wave device including: a piezoelectric layer; and a pair of interdigital electrodes provided on the piezoelectric layer, each of the pair of interdigital electrodes having a plurality of electrode fingers and a bus bar to which the plurality of electrode fingers are connected, an intersection region where the plurality of electrode fingers intersect each other including an edge region located at an edge in a longitudinal direction of the plurality of electrode fingers, a central region located inside the edge region, and an intermediate region located between the edge region and the central region; wherein a first sound velocity of an acoustic wave propagating in the intermediate region is slower than a second sound velocity of the acoustic wave propagating in the central region and a third sound velocity of the acoustic wave propagating in the edge region is faster than the second sound velocity.

According to a third aspect of the present embodiments, there is provided a filter including the above acoustic wave device.

According to a fourth aspect of the present embodiments, there is provided a multiplexer including the above filter.

### BRIEF DESCRIPTION OF THE DRAWINGS

FIG. 1A is a plan view of an acoustic wave device according to a first embodiment;

FIG. 1B is a cross-sectional view taken along a line A-A in FIG. 1A;

FIG. 2A is a plan view of an acoustic wave device according to a comparative example;

FIG. 2B is a cross-sectional view taken along a line A-A in FIG. 2A;

FIG. 3A is a graph illustrating the sound velocity of an acoustic wave in the comparative example;

FIG. 3B is a graph illustrating the sound velocity of an acoustic wave in the first embodiment;

FIG. 4 is a diagram illustrating the length of a low sound velocity region in a Y direction with respect to a difference in the sound velocity of the low sound velocity region in simulation 1;

FIG. 5A is a plan view of an acoustic wave device used in simulation 2;

FIG. 5B is a diagram illustrating a difference in sound velocity of an acoustic wave with respect to a duty ratio in the simulation 2;

FIGS. 6A to 6C are cross-sectional views of electrode fingers in the first embodiment;

FIG. 7A is a plan view of an acoustic wave device according to a first modification of the first embodiment;

FIG. 7B is a plan view of an acoustic wave device according to a second modification of the first embodiment;

FIG. 8A is a plan view of an acoustic wave device according to a third modification of the first embodiment;

FIG. 8B is a cross-sectional view taken along a line A-A in FIG. 8A;

FIG. 9A is a plan view of an acoustic wave device according to a fourth modification of the first embodiment;

FIG. 9B is a plan view of an acoustic wave device according to a fifth modification of the first embodiment;

FIG. 10A is a plan view of an acoustic wave device according to a sixth modification of the first embodiment;

FIG. 10B is a cross-sectional view taken along a line A-A in FIG. 10A;

FIG. 11A is a plan view of an acoustic wave device according to a seventh modification of the first embodiment;

FIG. 11B is a cross-sectional view taken along a line A-A in FIG. 11A;

FIG. 11C is a diagram illustrating the sound velocity of an acoustic wave;

FIG. 12A is a plan view of an acoustic wave device according to a second embodiment;

FIG. 12B is a cross-sectional view taken along a line A-A in FIG. 12A;

FIG. 12C is a diagram illustrating the sound velocity of an acoustic wave;

FIG. 13A is a circuit diagram of a filter according to a third embodiment; and

FIG. 13B is a circuit diagram of a duplexer according to a modification of the third embodiment.

### DETAILED DESCRIPTION

A difference between the sound velocity of the acoustic wave in a gap region located between the electrode finger and the bus bar and the sound velocity of the acoustic wave in the central region may be large. In this case, the width of the edge region is increased in order to realize the piston mode. However, when the width of the edge region is increased, the acoustic wave device increases in size.

An object of the present disclosure is to suppress an increase in the size of the acoustic wave device.

Hereinafter, embodiments of the present invention will be described with reference to the drawings.

### First Embodiment

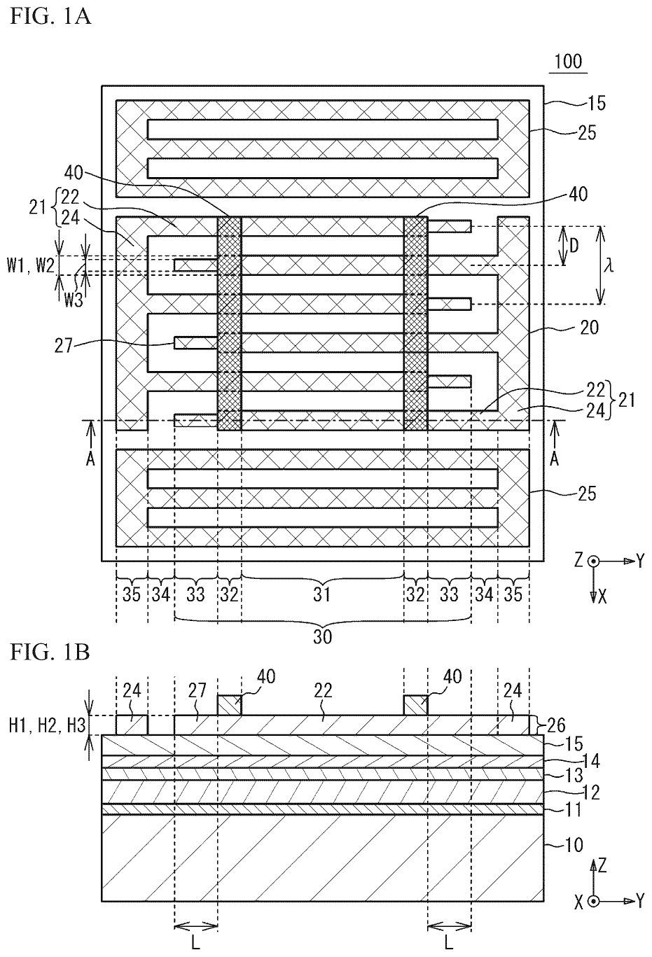

FIG. 1A is a plan view of an acoustic wave device 100 according to a first embodiment, and FIG. 1B is a cross-sectional view taken along a line A-A in FIG. 1A. The transverse direction of electrode fingers 22 is defined as an X direction, the longitudinal direction of the electrode fingers 22 is defined as a Y direction, and the lamination direction of a substrate 10 and a piezoelectric layer 15 is defined as a Z direction. The X direction, the Y direction, and the Z direction do not necessarily correspond to the X axis direction of the crystal orientation of the piezoelectric layer 15. When the piezoelectric layer 15 is a piezoelectric layer of a rotated Y-cut X-propagation, the X direction is the X-axis direction of the crystal orientation.

As illustrated in FIGS. 1A and 1B, the piezoelectric layer 15 is provided on the substrate 10. A first insulating layer 11 is provided between the substrate 10 and the piezoelectric layer 15. A second insulating layer 12 is provided between the first insulating layer 11 and the piezoelectric layer 15. A third insulating layer 13 is provided between the second insulating layer 12 and the piezoelectric layer 15. A fourth insulating layer 14 is provided between the third insulating layer 13 and the piezoelectric layer 15. The substrate 10 is, for example, a sapphire substrate. The first insulating layer 11 is a porous aluminum oxide layer having many voids such as holes. The second insulating layer 12 is, for example, an aluminum oxide layer having fewer voids than the first insulating layer 11. The third insulating layer 13 is, for example, an aluminum nitride layer. The fourth insulating layer 14 is, for example, a silicon oxide layer. The piezoelectric layer 15 is, for example, a single-crystal lithium tantalate layer, a single-crystal lithium niobate layer, or a single-crystal quartz layer. The piezoelectric layer 15 may be, for example, a rotated Y-cut X-propagating lithium tantalate layer or a rotated Y-cut X-propagating lithium niobate layer, or may be, for example, a rotated 30° to 50° Y-cut X-propagating lithium tantalate layer.

An IDT (Interdigital Transducer) 20 and a reflector 25 are provided on the piezoelectric layer 15. The IDT 20 includes a pair of interdigital electrodes 21. The interdigital electrode 21 has the plurality of electrode fingers 22 and a bus bar 24 to which the plurality of electrode fingers 22 are connected. The IDT 20 and the reflector 25 are formed by a metal film 26 on the piezoelectric layer 15. The metal film 26 contains at least a metal having a density higher than that of copper (Cu) and contains at least one metal layer, for example, tungsten (W), molybdenum (Mo), ruthenium (Ru), platinum (Pt), iridium (Ir), rhenium (Re), rhodium (Rh) or tantalum (Ta) as a main component. Examples of material densities are given in Table 1.

TABLE 1

| | Cu | W | Mo | Ru | Pt | Ir | Re | Rh | Ta |
|---|---|---|---|---|---|---|---|---|---|
| DEN- | 8.92 | 19.25 | 10.28 | 12.37 | 21.45 | 22.65 | 21.02 | 12.41 | 16.65 |
| SITY | | | | | | | | | |
| [g/cm³] | | | | | | | | | |

Here, in order for a certain film to contain a certain element as a main component, it is allowed that a certain film contains intentional or unintentional impurities other than the main component. When an element is a main component in a certain film, the concentration of the element is, for example, 50 atomic % or more, and, for example, 80 atomic % or more. In the case where two or more elements are used as the main components, as in the case of silicon oxide or the like, the total concentration of the two or more elements is 50 atomic % or more, 80 atomic % or more, or 90 atomic % or more. Each of the two or more elements is 10 atomic % or more or 20 atomic %. As an example, in the case of silicon oxide, the sum of the silicon concentration and the oxygen concentration is 50 atomic % or more, 80 atomic % or more, or 90 atomic % or more. Each of the concentration of silicon and the concentration of oxygen is, for example, 10 atomic % or more or 20 atomic % or more.

A region where the electrode fingers 22 of the pair of interdigital electrodes 21 intersect each other is an intersection region 30. The length of the intersection region 30 in the Y direction is an aperture. The pair of interdigital electrodes 21 are opposed to each other in such a manner that the electrode fingers 22 are alternately arranged in the X direction in at least a part of the intersection region 30. The acoustic wave (surface acoustic wave) of the main mode excited by the electrode fingers 22 in the intersection region 30 is mainly propagated in the X direction. The pitch of the electrode fingers 22 of the interdigital electrode 21 is substantially equal to a wavelength λ of the surface acoustic wave. The wavelength λ is substantially twice an average pitch D of the plurality of electrode fingers 22. Reflectors 25 reflect the surface acoustic wave excited by the electrode fingers 22 of the IDT 20. As a result, the surface acoustic wave is confined in the intersection region 30 of the IDT 20.

The intersection region 30 has edge regions 33 positioned at the edge in the Y direction, a central region 31 positioned further inside than the edge regions 33 in the Y direction, and intermediate regions 32 positioned between the central region 31 and the edge regions 33. The edge region 33 is a region in the intersection region 30 where a tip portion 27 of the electrode finger 22 is located. Each of gap regions 34 is a region located between the tip of the electrode finger 22 of one interdigital electrode 21 and the bus bar 24 of the other interdigital electrode 21. Regions where the bus bars 24 are located are bus bar regions 35.

Additional films 40 are provided on the piezoelectric layer 15 in the intermediate regions 32. The additional film 40 is provided in a band shape in the X direction and covers the electrode fingers 22 located in the intermediate region 32. The additional film 40 is not provided in the central region 31, the edge region 33, the gap region 34, and the bus bar region 35. The additional film 40 is an insulating film containing, for example, silicon oxide (SiO₂), tantalum oxide (Ta₂O₅), or niobium oxide (Nb₂O₅) as a main component. The additional film 40 may be a single layer or multilayer film which contains other materials as a main component as long as the sound velocity of the acoustic wave propagating through the intermediate region 32 can be adjusted.

The tip portion 27 of the electrode finger 22 has a width, which is a length in the X direction, smaller than that of the other portion of the electrode finger 22. Therefore, a width W3 of the electrode finger 22 in the edge region 33 is smaller than a width W1 of the electrode finger 22 in the central region 31 and a width W2 of the electrode finger 22 in the intermediate region 32. The height of the electrode finger 22 in the Z direction is constant from one end connected to the bus bar 24 to the other end which is a tip of the opposite side. Therefore, a height H3 of the electrode finger 22 in the edge region 33 is the same as a height H1 of the electrode finger 22 in the central region 31 and a height H2 of the electrode finger 22 in the intermediate region 32. The same height allows for manufacturing errors.

### Manufacturing Method

A method of manufacturing the acoustic wave device 100 according to the first embodiment will be described. First, the first insulating layer 11, the second insulating layer 12, the third insulating layer 13, and the fourth insulating layer 14 are formed in this order on the substrate 10. The first insulating layer 11, the second insulating layer 12, the third insulating layer 13, and the fourth insulating layer 14 are formed by, for example, sputtering, CVD (Chemical Vapor Deposition), or vacuum deposition. Next, the piezoelectric layer 15 is bonded to the fourth insulating layer 14 by, for example, a surface activation method, and then the piezoelectric layer 15 is polished to a desired thickness by, for example, a CMP (Chemical Mechanical Polishing) method. Next, the metal film 26 is formed on the piezoelectric layer 15, and then the metal film 26 is patterned into a desired shape. As a result, the IDT 20 and the reflectors 25 are formed on the piezoelectric layer 15. The metal film 26 is formed by, for example, sputtering, CVD, or vacuum evaporation. The patterning of the metal film 26 is performed by, for example, photolithography and etching.

Next, the additional film 40 covering the electrode fingers 22 is formed on the piezoelectric layer 15 in the intermediate region 32. The additional film 40 is formed by forming a mask layer having an opening in the intermediate region 32 on the piezoelectric layer 15, forming the additional film 40 using the mask layer as a mask, and then removing the mask layer. The mask layer is formed of, for example, a photoresist. The additional film 40 is formed by, for example, sputtering, CVD, or vacuum deposition. Thus, the acoustic wave device 100 according to the first embodiment is formed.

### Comparative Example

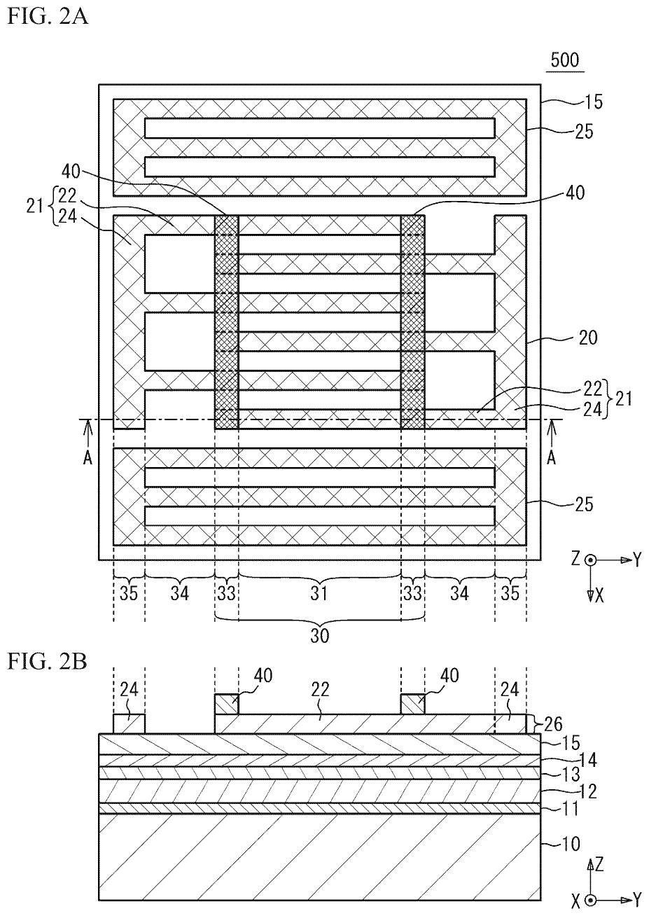

FIG. 2A is a plan view of an acoustic wave device 500 according to a comparative example, and FIG. 2B is a cross-sectional view taken along a line A-A in FIG. 2A. As illustrated in FIGS. 2A and 2B, in the comparative example, the intersection region 30 has the central region 31 and the edge regions 33. The additional film 40 is provided on the piezoelectric layer 15 in the edge region 33 so as to cover the electrode fingers 22. The additional film 40 is not provided in the central region 31, the gap region 34, and the bus bar region 35. The width and height of the electrode fingers 22 are constant from one end connected to the bus bar 24 to the other end which is a tip of the opposite side. The other components are the same as those of the first embodiment, and therefore, the description thereof is omitted.

### Sound Velocity of Acoustic Wave

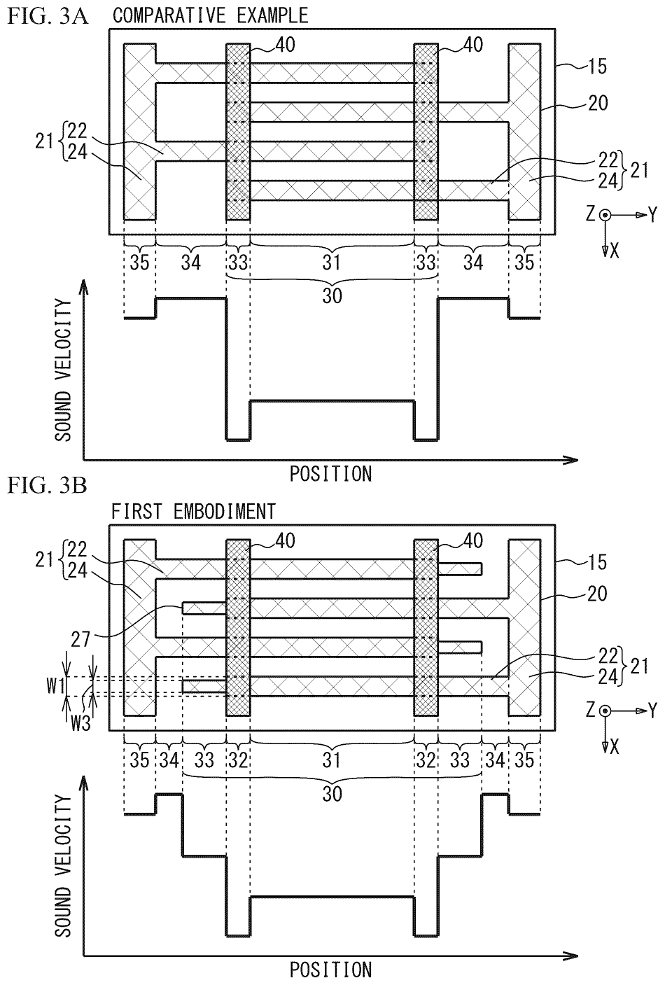

FIG. 3A is a graph illustrating the sound velocity of an acoustic wave in the comparative example. As illustrated in FIG. 3A, in the comparative example, since the additional film 40 is provided in the edge region 33, the sound velocity of the acoustic wave propagating in the edge region 33 is lower than the sound velocity of the acoustic wave propagating in the central region 31. Since the gap region 34 has a smaller number of electrode fingers 22 than the central region 31, the acoustic velocity of the acoustic wave propagating through the gap region 34 is higher than that of the acoustic wave propagating through the central region 31. The piston mode can be realized by setting the edge region 33 as a low sound velocity region where the sound velocity of the acoustic wave is slower than that of the central region 31 and setting the gap region 34 as a high sound velocity region where the sound velocity of the acoustic wave is faster than that of the central region 31.

However, when the electrode finger 22 includes a metal layer containing a heavy metal such as W, Mo, Ru, Pt, Ir, Re, Rh, or Ta as the main component, the difference between the sound velocity of the acoustic wave in the gap region 34 and the sound velocity of the acoustic wave in the central region 31 is increased. In this case, in order to establish the piston mode, the length of the edge region 33 in the Y direction is increased, and therefore the device increases in size.

FIG. 3B is a graph illustrating the sound velocity of an acoustic wave in the first embodiment. As illustrated in FIG. 3B, in the first embodiment, since the additional film 40 is provided in the intermediate region 32, the sound velocity of the acoustic wave propagating in the intermediate region 32 is lower than the sound velocity of the acoustic wave propagating in the central region 31. Since the width W3 of the electrode finger 22 in the edge region 33 is smaller than the width W1 of the electrode finger 22 in the central region 31, the sound velocity of the acoustic wave propagating in the edge region 33 is higher than the sound velocity of the acoustic wave propagating in the central region 31. In this case, in the piston mode, the intermediate region 32 is a low sound velocity region where the sound velocity of the acoustic wave is lower than that of the central region 31, and the edge region 33 is a high sound velocity region where the sound velocity of the acoustic wave is higher than that of the central region 31. By appropriately reducing the width W3 of the electrode finger 22 in the edge region 33 with respect to the width W1 of the electrode finger 22 in the central region 31, the sound velocity of the acoustic wave in the edge region 33 can be set to an appropriate velocity with respect to the sound velocity of the acoustic wave in the central region 31. This makes it possible to suppress the length of the edge region 33 in the Y direction from increasing, and to suppress the size of the device from increasing. Since the edge region 33 is the high sound velocity region, the length of the gap region 34 in the Y direction may be about 300 nm. Therefore, the distance between the additional film 40 and the bus bar 24 in the Y direction is almost the same as that of the comparative example, and thus the device is hardly enlarged in this respect. Since the gap region 34 is provided outside the edge region 33, the surface acoustic wave excited by the IDT 20 can be confined in the intersection region 30 in a good manner.

### Simulation 1

For the acoustic wave devices according to the first embodiment and a comparative example, simulation was performed on the relationship between a difference in the sound velocity of the acoustic wave between the central region 31 and the low sound velocity region (i.e., the intermediate region 32 in the first embodiment and the edge region 33 in the comparative example) when the piston mode is established, and the length of the low sound velocity region in the Y direction. The difference in the sound velocity of the acoustic wave between the central region 31 and the low sound velocity region was obtained by an equation

$$“ difference in sound velocity = ( sound velocity of central region 31 - sound velocity of low sound velocity region ) / sound velocity of central region 31 ” .$$

The simulation conditions are as follows:
Common conditions of First Embodiment and Comparative Example
   Wavelength λ of surface acoustic wave: 4.1 μm
   Substrate 10: sapphire substrate of 38.4 μm thickness
   First insulating layer 11: none
   Second insulating layer 12: none
   Third insulating layer 13: None
   Fourth insulating layer 14: silicon oxide layer of 0.83 μm thickness
   Piezoelectric layer 15: 42° rotated Y-cut X-propagated lithium tantalate layer of 1.25 μm thickness
   IDT 20, reflector 25: film including titanium layer of 10 nm thickness, tungsten layer of 220 nm thickness and aluminum layer of 230 nm thickness laminated in this order
   Additional film 40: silicon oxide film of 150 nm thickness
   Aperture: 80.2 μm
   Number of pairs of electrode fingers 22: 60 pairs
   Duty ratio in central area 31 of IDT 20: 50%
   Length of bus bar region 35 in Y direction: 12.3 μm
Conditions of First Embodiment
   Length of gap region 34 in Y direction: 4.1 μm
   Length of edge region 33 in Y direction: 4.1 μm
   Length of intermediate region 32 in Y direction: 3.69 μm
   Duty ratio of edge region 33 of IDT 20: 40%
   Difference A1 in sound velocity between acoustic waves in central region 31 and edge region 33: 3%

$$Difference A 1 in sound velocity = ( sound velocity of edge region 33 - sound velocity of central region 31 ) \text{} / sound velocity of central region 31$$

Conditions of Comparative Example
   Length of gap region 34 in Y direction: 8.2 μm
   Length of edge region 33 in Y direction: 5.33 μm
   Difference A2 in sound velocity between acoustic wave in central region 31 and gap region 34: 20%

$$Difference A 2 in sound velocity = ( sound velocity of gap region 34 - sound velocity of central region 31 ) \text{} / sound velocity of central region 31$$

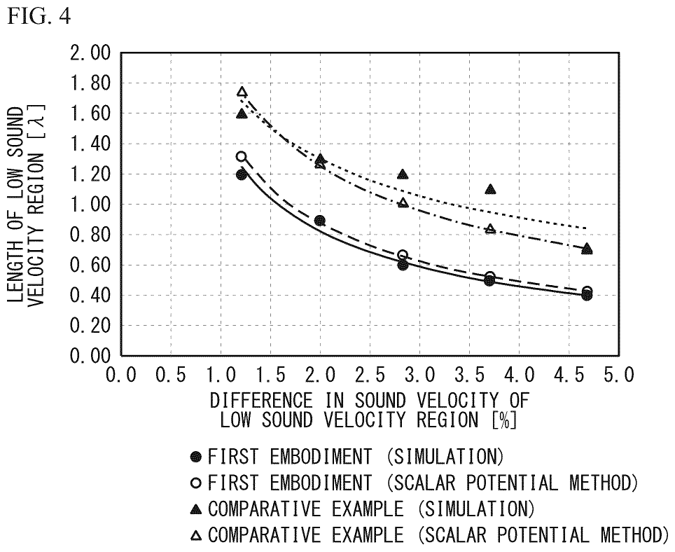

FIG. 4 is a diagram illustrating the length of the low sound velocity region in the Y direction with respect to the difference in the sound velocity in the low sound velocity region in the simulation 1. A horizontal axis in FIG. 4 represents the difference in acoustic velocity of the acoustic wave between the central region 31 and the low sound velocity region (i.e., the intermediate region 32 in the first embodiment, and the edge region 33 in the comparative example). A vertical axis represents the length of the low sound velocity region in the Y direction. In FIG. 4, the simulation results of the first embodiment are indicated by black circles, the simulation results of the comparative example are indicated by black triangles, and respective approximate curves are indicated by a solid line and a dotted line. When the conditions for establishing the piston mode at the difference A1 in sound velocity of the first embodiment and the difference A2 in sound velocity of the comparative example are calculated by a scalar potential method, the calculation results of the first embodiment are indicated by white circles, the calculation results of the comparative example are indicated by white triangles, and respective approximate curves are indicated by a broken line and an alternate long and short dash line.

As illustrated in FIG. 4, the results calculated using the scalar potential method and the simulation results are similar, and in both cases, when the differences in sound velocity in the low sound velocity region are the same as each other, the length in the Y direction of the low sound velocity region for establishing the piston mode is smaller in the first embodiment than in the comparative example. From this, it is understood that the first embodiment can realize the piston mode while suppressing the increase in the size of the device as compared with the comparative example. If the difference in sound velocity in the low sound velocity region is increased, the length of the low sound velocity region in the Y direction is reduced, but increasing the difference in sound velocity in the low sound velocity region means increasing the thickness of the additional film 40, and therefore, there is a concern about the generation of burrs during manufacturing, an insufficient film thickness of the mask layer, and the like, and an increase in the size of the device due to the height increase also occurs.

### Simulation 2

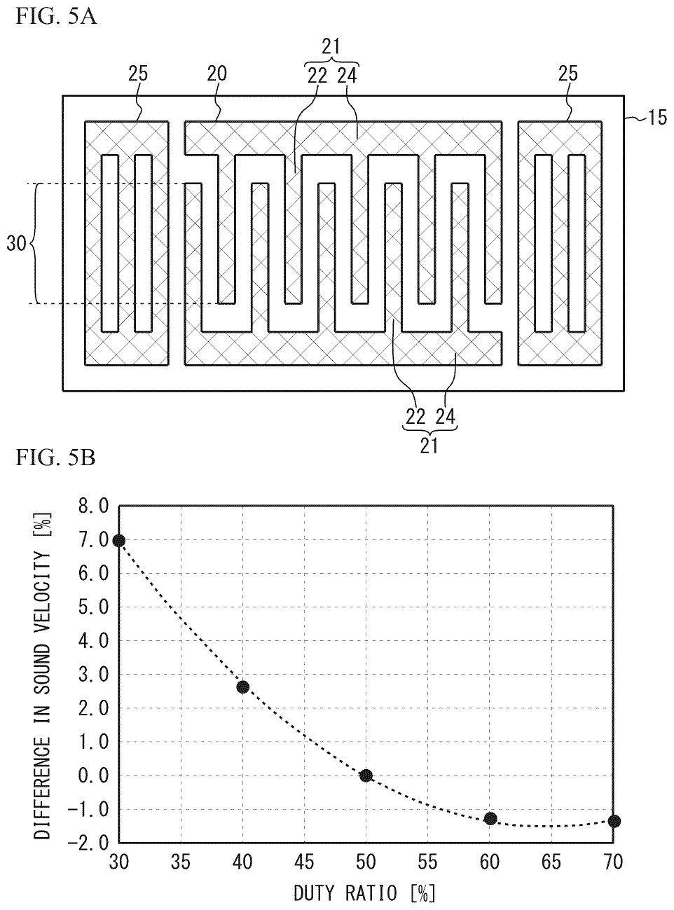

The relationship between the duty ratio and the sound velocity of the IDT 20 was simulated. FIG. 5A is a plan view of the acoustic wave device used in the simulation 2. As illustrated in FIG. 5A, in the simulation 2, the electrode finger 22 provided on the piezoelectric layer 15 has a constant width and a constant height from one end connected to the bus bar 24 to the other end which is a tip of the opposite side. The additional film 40 is not provided on the piezoelectric layer 15. For the acoustic wave device having such a structure, simulation was performed on the sound velocity of the acoustic wave propagating through the intersection region 30 by changing the duty ratio of the IDT 20. The duty ratio of the IDT 20 is (the width of the electrode finger 22)/(the pitch of the electrode finger 22).

FIG. 5B is a diagram illustrating the difference in sound velocity of the acoustic wave with respect to the duty ratio in the simulation 2. In FIG. 5B, a horizontal axis represents the duty ratio, and a vertical axis represents the difference in sound velocity with respect to the sound velocity when the duty ratio is 50%. As illustrated in FIG. 5B, the acoustic velocity of the acoustic wave is increased by about 3% when the duty ratio of the IDT 20 is 40%, and by about 7% when the duty ratio of the IDT 20 is 30%, as compared with the case where the duty ratio of the IDT 20 is 50%.

From the results of the simulation 2, it is understood that, in the first embodiment, by appropriately reducing the width W3 of the electrode finger 22 in the edge region 33, the sound velocity of the acoustic wave in the edge region 33 can be set to be an appropriate velocity with respect to the sound velocity of the acoustic wave in the central region 31. Since it is preferable that the sound velocity of the acoustic wave in the high sound velocity region is higher by about 2% to 7% than the sound velocity of the acoustic wave in the central region, it is preferable that the width W3 of the electrode finger 22 in the edge region 33 is set to about 60% to 80% of the width W1 of the electrode finger 22 in the central region 31.

In the first embodiment, the length L (see FIG. 1B) of each of the edge regions 33 in the Y direction is 0.1 λ or more and 1.5 λ or less. This is because the excitation of the acoustic wave in the edge region 33 increases as the length L increases, which leads to the generation of an unnecessary spurious. On the other hand, this is because if the length Lis reduced, the gap region 34 functions as the high sound velocity region in the piston mode.

In order to realize the piston mode, it is preferable that the length of the central region 31 in the Y direction and the length of the intermediate region 32 in the Y direction satisfy a predetermined relationship. For example, it is preferable that the length of the central region 31 in the Y direction is longer than the total length of the intermediate regions 32 in the Y direction. The length of each of the intermediate regions 32 in the Y direction is preferably 1.0 λ or less, and more preferably 0.5 λ or less. The length of each of the intermediate regions 32 in the Y direction is preferably 0.05 λ or more, and more preferably 0.1 λ or more. The intermediate region 32 and the edge region 33 may be provided only on one side of the central region 31.

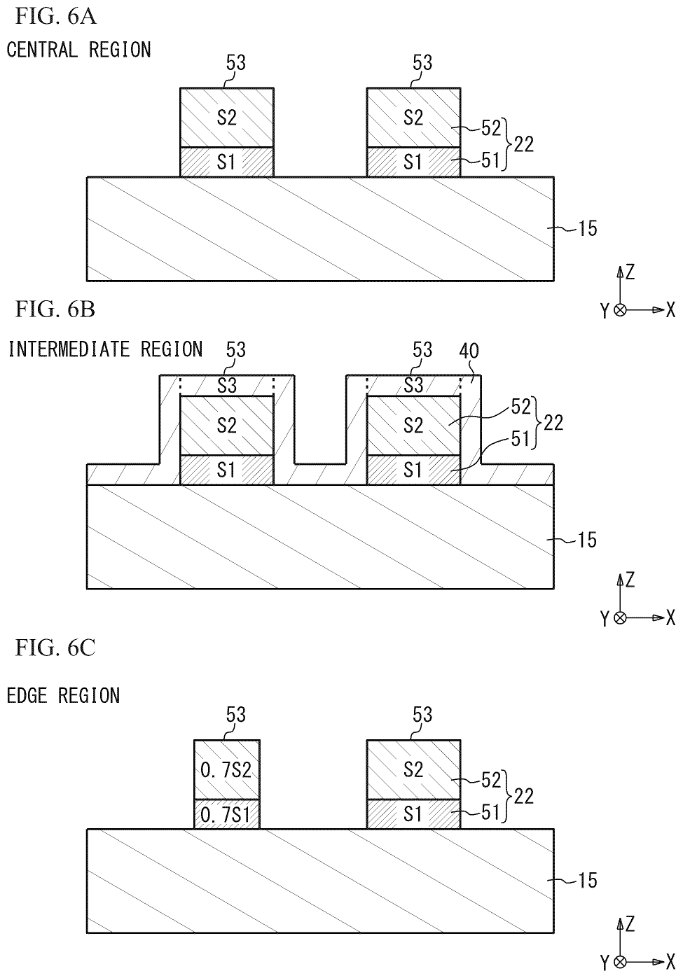

FIGS. 6A to 6C are cross-sectional views of the electrode fingers 22 in the first embodiment. FIG. 6A is a cross-sectional view of the electrode fingers 22 in the central region 31 in the X direction, FIG. 6B is a cross-sectional view of the electrode fingers 22 in the intermediate region 32 in the X direction, and FIG. 6C is a cross-sectional view of the electrode fingers 22 in the edge region 33 in the X direction. In FIGS. 6A to 6C, the electrode finger 22 is a film in which a first metal layer 51 and a second metal layer 52 are laminated. The electrode finger 22 is not limited to the laminated films or multilayer film, but may be a single-layer film.

As illustrated in FIGS. 6A and 6B, when the central region 31 and the intermediate region 32 are compared, the width and height of the electrode fingers 22 are the same as each other, but the additional film 40 is provided on the electrode fingers 22 in the intermediate region 32.

As illustrated in FIGS. 6A and 6C, when the central region 31 and the edge region 33 are compared, at least some of the electrode fingers 22 have a width in the edge region 33 smaller than a width in the central region 31. The heights of the electrode fingers 22 are the same as each other in the central region 31 and the edge region 33.

As illustrated in FIG. 6A, the cross-sectional area of the first metal layer 51 is S1, and the cross-sectional area of the second metal layer 52 is S2. The density of the metal material of the main component of the first metal layer 51 is ρ1, and the density of the metal material of the main component of the second metal layer 52 is ρ2. In this case, the weight per unit length in the Y direction obtained by multiplying the cross-sectional area of the first metal layer 51 by the density is denoted by “S1×ρ1”, and the weight per unit length in the Y direction obtained by multiplying the cross-sectional area of the second metal layer 52 by the density is denoted by “S2×ρ2”. Accordingly, the weight per unit length in the Y direction (referred to as a first weight) of films 53 including the first metal layers 51 and the second metal layers 52 of the electrode fingers 22 provided on the piezoelectric layer 15 at the positions where the electrode fingers 22 are located is denoted by “S1×ρ1+S2×ρ2”.

As illustrated in FIG. 6B, in the intermediate region 32, the additional film 40 is provided on the electrode fingers 22. The cross-sectional area of the additional film 40 on the electrode fingers 22 is S3. The density of the main constituent material of the additional film 40 is ρ3. In this case, the weight per unit length in the Y direction obtained by multiplying the cross-sectional area of the additional film 40 by the density is denoted by “S3×ρ3”. Accordingly, the weight per unit length in the Y direction (referred to as a second weight) of the films 53 including the first metal layers 51 and the second metal layers 52 of the electrode fingers 22 provided on the piezoelectric layer 15 at the positions where the electrode fingers 22 are positioned is denoted by “S1×ρ1+S2×ρ2+S3×ρ3”. Therefore, the second weight is greater than the first weight.

As illustrated in FIG. 6C, at least one of the plurality of electrode fingers 22 has the width of the electrode finger 22 in the edge region 33 smaller than the width of the electrode finger 22 in the central region 31. For example, the width of the electrode finger 22 in the center region 31 is 70% of the width of the electrode finger 22 in the center region 31. In this case, the cross-sectional area of the first metal layer 51 is 0. 7S1, and the cross-sectional area of the second metal layer 52 is 0. 7S2. Accordingly, the weight per unit length in the Y direction (referred to as a third weight) of the films 53 including the first metal layers 51 and the second metal layers 52 of the electrode fingers 22 provided on the piezoelectric layer 15 at the positions where the electrode fingers 22 are located is denoted by “0. 7S1×ρ1+0. 7S2×ρ2”. Therefore, the third weight is smaller than the first weight.

When the second weight is larger than the first weight and the third weight is smaller than the first weight, the sound velocity of the acoustic wave in the intermediate region 32 is slower than the sound velocity of the acoustic wave in the central region 31, and the sound velocity of the acoustic wave in the edge region 33 is faster than the sound velocity of the acoustic wave in the central region 31, as illustrated in FIG. 3B. Accordingly, the intermediate region 32 is the low sound velocity region in the piston mode, and the edge region 33 is the high sound velocity region.

As described above, the weight per unit length in the Y direction of the films 53 provided on the piezoelectric layer 15 at the positions where the electrode fingers 22 are positioned in the central region 31, the intermediate region 32, and the edge region 33 can be obtained from the cross-sectional area and the constituent material of the electrode fingers 22 by observing the cross-section of the electrode fingers 22 in the central region 31, the intermediate region 32, and the edge region 33. When the sum of the first weights, the sum of the second weights, and the sum of the third weights of the plurality of electrode fingers 22, such as two or four electrode fingers 22, that are continuous in the X direction are compared, the sum of the second weights is greater than the sum of the first weights, and the sum of the third weights is less than the sum of the first weights.

### Modification

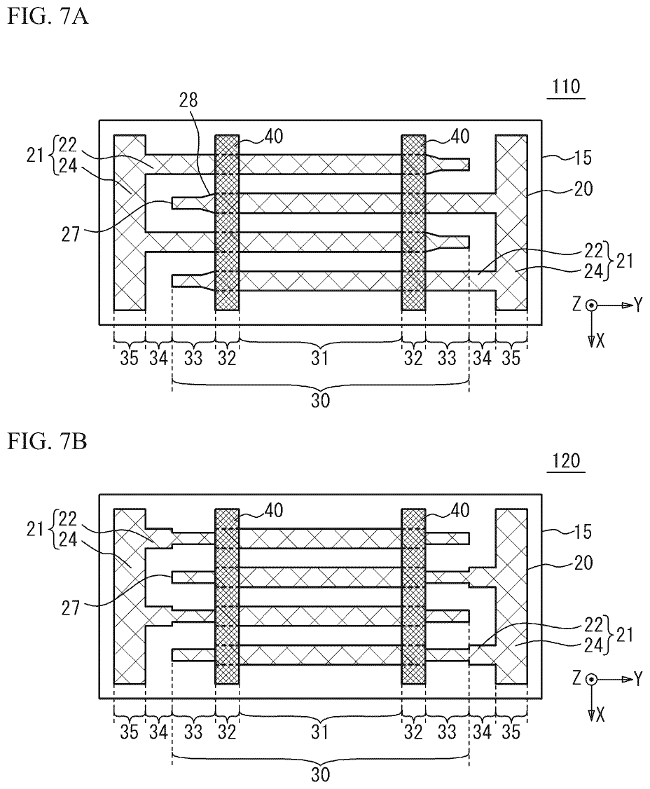

FIG. 7A is a plan view of an acoustic wave device 110 according to a first modification of the first embodiment. As illustrated in FIG. 7A, in the first modification of the first embodiment, the tip portion 27 of the electrode finger 22 has a wide portion 28 having a wide width in the vicinity of the intermediate region 32. The wide portion 28 becomes narrower as it is further away from the intermediate region 32. The other components are the same as those of the first embodiment, and therefore, the description thereof is omitted. The tip portion 27 of the electrode finger 22 has the wide portion 28 in the vicinity of the intermediate region 32, whereby the power durability can be improved. From the viewpoint of realizing the piston mode, the length of the wide portion 28 in the Y direction is preferably equal to or less than ⅕ of the length of the edge region 33 in the Y direction, more preferably equal to or less than 1/10 of the length of the edge region 33 in the Y direction, and still more preferably equal to or less than 1/20 of the length of the edge region 33 in the Y direction.

FIG. 7B is a plan view of an acoustic wave device 120 according to a second modification of the first embodiment. As illustrated in FIG. 7B, in the second modification of the first embodiment, the electrode finger 22 has a small width at the tip end portion 27 located in the edge region 33, and also has a small width at a portion located in the edge region 33 on the opposite side to the tip portion 27. The other components are the same as those of the first embodiment, and therefore, the description thereof is omitted. The width of only the portion located in the edge region 33 on the opposite side to the tip portion 27 may be reduced without reducing the width of the tip portion 27 of the electrode finger 22.

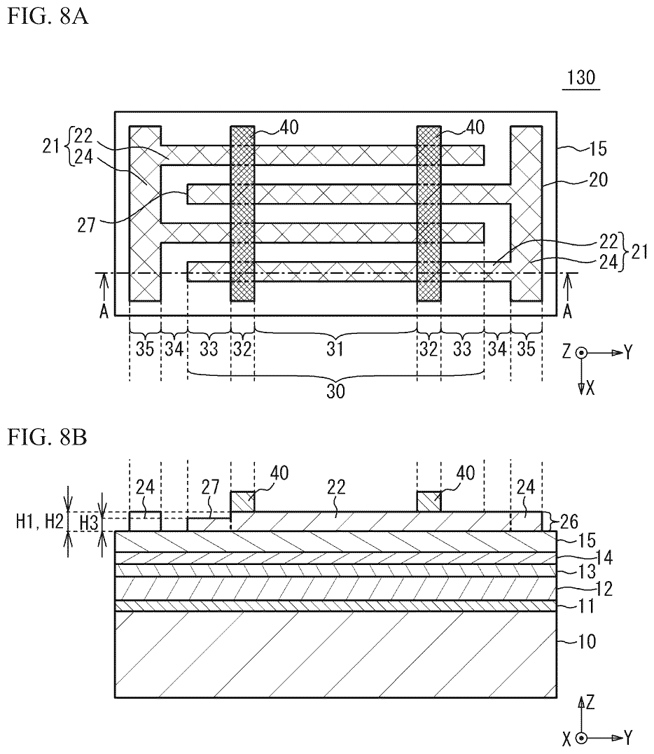

FIG. 8A is a plan view of an acoustic wave device 130 according to a third modification of the first embodiment, and FIG. 8B is a cross-sectional view taken along a line A-A in FIG. 8A. As illustrated in FIGS. 8A and 8B, in the third modification of the first embodiment, the width of the electrode fingers 22 is constant from one end connected to the bus bar 24 to the other end which is a tip of the opposite side. The height H3 of the tip portion 27 of the electrode finger 22 in the edge region 33 is smaller than the height H1 of the electrode finger 22 in the central region 31 and the height H2 of the electrode finger 22 in the intermediate region 32. The other components are the same as those of the first embodiment, and therefore, the description thereof is omitted.

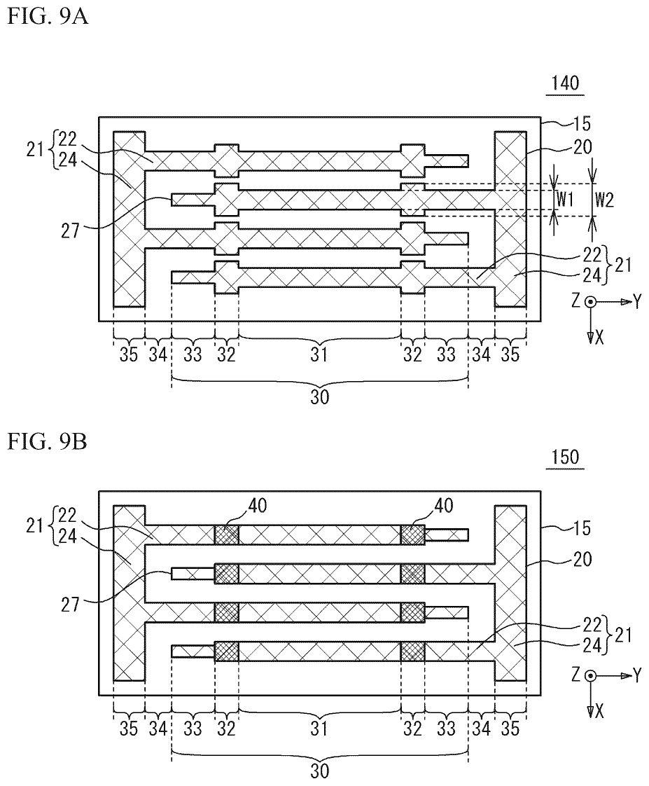

FIG. 9A is a plan view of an acoustic wave device 140 according to a fourth modification of the first embodiment. As illustrated in FIG. 9A, in the fourth modification of the first embodiment, the additional film 40 is not provided in the intermediate region 32. Instead, the width W2 of the electrode finger 22 in the intermediate region 32 is greater than the width W1 of the electrode finger 22 in the central region 31. The other components are the same as those of the first embodiment, and therefore, the description thereof is omitted.

FIG. 9B is a plan view of an acoustic wave device 150 according to a fifth modification of the first embodiment. As illustrated in FIG. 9B, in the fifth modification of the first embodiment, the additional film 40 provided in the intermediate region 32 is provided only on the electrode fingers 22 and is not provided between the electrode fingers 22. That is, in the first embodiment, the additional film 40 is provided in the band shape, but in the fifth modification of the first embodiment, the additional film 40 is provided in a dot shape. The other components are the same as those of the first embodiment, and therefore, the description thereof is omitted.

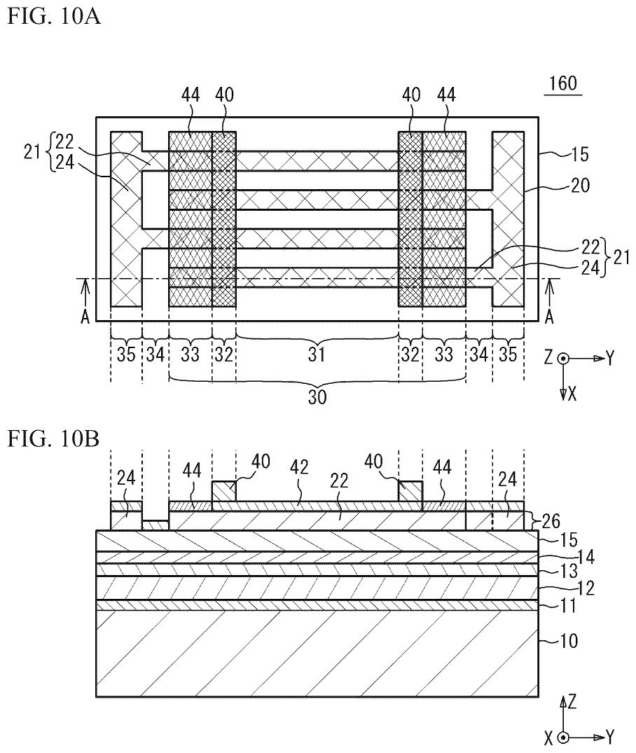

FIG. 10A is a plan view of an acoustic wave device 160 according to a sixth modification of the first embodiment, and FIG. 10B is a cross-sectional view taken along a line A-A in FIG. 10A. In FIG. 10A, the protective film 42 is not illustrated for the sake of clarity. As illustrated in FIGS. 10A and 10B, in the sixth modification of the first embodiment, a protective film 42 covering the electrode fingers 22 and the bus bars 24 is provided on the piezoelectric layer 15 in the central region 31, the intermediate region 32, the gap region 34, and the bus bar region 35. In the edge region 33, a protective film 44 which covers the electrode fingers 22 and contains a material having a higher sound velocity than the protective film 42 as a main component is provided on the piezoelectric layer 15. Since the sound velocity is obtained by calculating the square root of the value obtained by dividing the Young's modulus by the density, for example, the protective film 42 is a film containing silicon oxide as a main component, and the protective film 44 is a film aluminum oxide or silicon nitride as a main component. The thickness of the protective film 42 is the same as that of the protective film 44. The other components are the same as those of the first embodiment, and therefore, the description thereof is omitted.

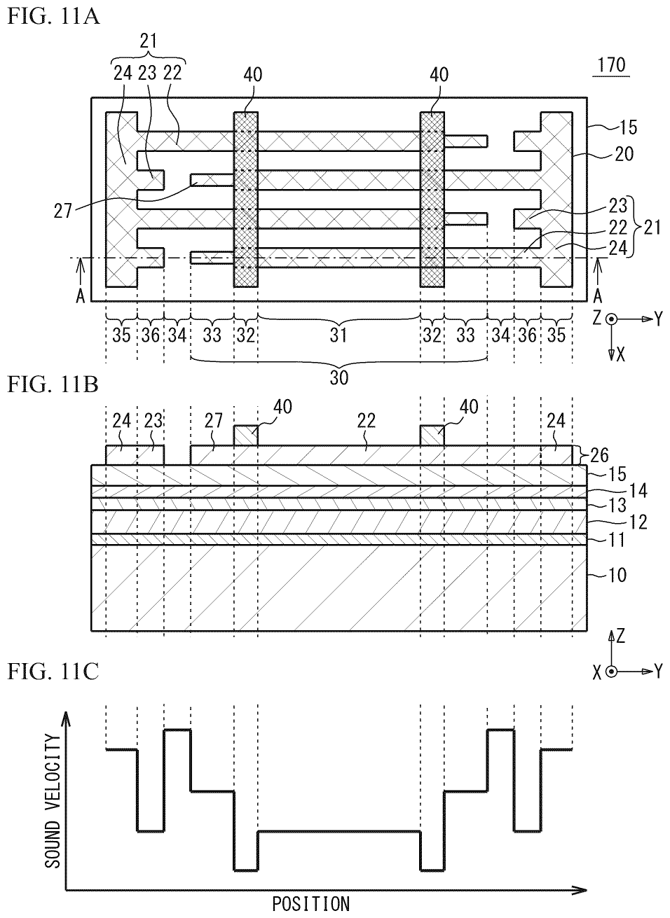

FIG. 11A is a plan view of an acoustic wave device 170 according to a seventh modification of the first embodiment, and FIG. 11B is a cross-sectional view taken along a line A-A in FIG. 11A. As illustrated in FIGS. 11A and 11B, in the seventh modification of the first embodiment, the interdigital electrode 21 has the plurality of electrode fingers 22, a plurality of dummy electrode fingers 23, and the bus bar 24. The dummy electrode finger 23 has the same width and the same height as the electrode finger 22 in the central region 31. A region where the dummy electrode fingers 23 are located is a dummy region 36. The other components are the same as those of the first embodiment, and therefore, the description thereof is omitted.

FIG. 11C is a graph illustrating the sound velocity of an acoustic wave in a seventh modification of the first embodiment. As illustrated in FIG. 11C, in the seventh modification of the first embodiment, since the dummy electrode fingers 23 provided in the dummy region 36 have the same width and the same height as the electrode fingers 22 in the central region 31, the sound velocity of the acoustic wave propagating in the dummy region 36 is the same as the sound velocity of the acoustic wave propagating in the central region 31. The other components are the same as those in FIG. 3B, and therefore, the description thereof is omitted.

In the first to the seventh modifications of the first embodiment, the weight per unit length in the Y direction of the single-layer or multilayer film including the metal layers of the electrode fingers 22 provided on the piezoelectric layer 15 at the positions where the electrode fingers 22 are positioned is configured such that the second weight in the intermediate region 32 is larger than the first weight in the central region 31, and the third weight in the edge region 33 is smaller than the first weight in the central region 31. Therefore, as in FIG. 3B, the sound velocity of the acoustic wave propagating through the intermediate region 32 is slower than that of the acoustic wave propagating through the central region 31, and the sound velocity of the acoustic wave propagating through the edge region 33 is faster than that of the acoustic wave propagating through the central region 31.

As described above, according to the first embodiment and the modification thereof, when the weight per unit length in the Y direction of the single-layer or multilayer film including the metal layers of the electrode finger 22 provided on the piezoelectric layer 15 at the location where at least one electrode finger 22 of the plurality of electrode fingers 22 is located is the first weight in the central region 31, the second weight in the intermediate region 32, and the third weight in the edge region 33, the second weight is larger than the first weight and the third weight is smaller than the first weight. That is, the sound velocity (first sound velocity) of the acoustic wave propagating through the intermediate region 32 is slower than the sound velocity (second sound velocity) of the acoustic wave propagating through the central region 31, and the sound velocity (third sound velocity) of the acoustic wave propagating through the edge region 33 is faster than the sound velocity (second sound velocity) of the acoustic wave propagating through the central region 31. Thus, the intermediate region 32 is the low sound velocity region where the sound velocity of the acoustic wave is lower than that of the central region 31, and the edge region 33 is the high sound velocity region where the sound velocity of the acoustic wave is higher than that of the central region 31, thereby realizing the piston mode. Further, since the sound velocity of the acoustic wave in the edge region 33 can be adjusted by the width and/or the height of the electrode fingers 22 located in the edge region 33, the sound velocity of the acoustic wave in the edge region 33 can be set to be an appropriate velocity with respect to the sound velocity of the acoustic wave in the central region 31. Therefore, the length of the intermediate region 32 in the Y direction can be suppressed from increasing, and the size of the device can be suppressed from increasing.

From the viewpoint of realizing the piston mode, the second weight is preferably more than 1.0 times and less than 2.0 times, more preferably 1.05 times or more and 1.6 times or less, and still more preferably 1.1 times or more and 1.4 times or less the first weight. The third weight is preferably more than 0.5 times and less than 1.0 times, more preferably 0.55 times or more and 0.9 times or less, and still more preferably 0.6 times or more and 0.8 times or less the first weight. The number of electrode fingers 22 having the second weight larger than the first weight and the third weight smaller than the first weight is preferably 50% or more of the entire electrode fingers 22, more preferably 80% or more of the entire electrode fingers 22, still more preferably 90% or more of the entire electrode fingers 22, and most preferably the entire electrode fingers 22. In addition, from the viewpoint of suppressing an increase in the length of the intermediate region 32 in the Y direction, the sound velocity (third sound velocity) of the acoustic wave propagating through the edge region 33 is preferably 1.01 times or more and 1.07 times or less, more preferably 1.02 times or more and 1.06 times or less, and still more preferably 1.03 times or more and 1.05 times or less the sound velocity (second sound velocity) of the acoustic wave propagating through the central region 31.

In addition, in the first embodiment, as illustrated in FIGS. 1A and 1B, the length L of the edge region 33 in the Y direction is three times or less (i.e., 1.5 λ or less) the average pitch D of the plurality of electrode fingers 22. This suppresses excitation of the acoustic wave in the edge region 33, and can suppress the occurrence of the spurious. From the viewpoint of suppressing the occurrence of the spurious, the length Lis preferably 2.5 times or less, more preferably 2 times or less, and still more preferably 1.5 times or less the average pitch D. In the first embodiment, the length Lis 0.2 times or more (0.1 λ or more) the average pitch D. This makes it possible to set the edge region 33 to the high sound velocity region. From the viewpoint of setting the edge region 33 to the high sound velocity region, the length Lis preferably 0.4 times or more, more preferably 0.6 times or more, and still more preferably 1.0 times or more the average pitch D. The average pitch D of the plurality of electrode fingers 22 can be calculated by dividing the width of the IDT 20 in the X direction by the number of electrode fingers 22.

In the first embodiment, as illustrated in FIG. 1A, the plurality of electrode fingers 22 include electrode fingers 22 each having the width W3 in the edge region 33 smaller than the width W1 in the central region 31. In such electrode fingers 22, the third weight in the edge region 33 is smaller than the first weight in the central region 31. Therefore, the sound velocity of the acoustic wave in the edge region 33 is faster than that of the acoustic wave in the central region 31, and the piston mode can be realized. By adjusting the ratio of the decrease in the width W3 of the electrode finger 22 in the edge region 33 to the width W1 of the electrode finger 22 in the central region 31, the sound velocity of the acoustic wave in the edge region 33 can be set to be an appropriate velocity with respect to the sound velocity of the acoustic wave in the central region 31. Therefore, the intermediate region 32 can be suppressed from increasing in length in the Y direction.

The width of the electrode finger 22 in the edge region 33 is not limited to the case of only the tip portion 27 of the electrode finger 22 as illustrated in FIG. 1A, but may be the case of both the tip portion 27 and the portion opposite to the tip portion 27 as illustrated in FIG. 7B. However, from the viewpoint of ensuring the power durability, it is preferable that only the width of the tip portion 27 is made small.

In the third modification of the first embodiment, as illustrated in FIGS. 8A and 8B, the plurality of electrode fingers 22 include electrode fingers 22 each having the height H3 in the edge region 33 smaller than the height Hl in the central region 31. In such electrode fingers 22, the third weight in the edge region 33 is smaller than the first weight in the central region 31. Therefore, the sound velocity of the acoustic wave in the edge region 33 is faster than that of the acoustic wave in the central region 31, and the piston mode can be realized. By adjusting the ratio of the decrease in height H3 of the electrode finger 22 in the edge region 33 to the height H1 of the electrode finger 22 in the central region 31, the sound velocity of the acoustic wave in the edge region 33 can be set to be an appropriate velocity with respect to the sound velocity of the acoustic wave in the central region 31. Therefore, the intermediate region 32 can be suppressed from increasing in length in the Y direction.

It is also possible to adjust both the width and the height of the electrode fingers 22 in the edge region 33 so that the sound velocity of the acoustic wave in the edge region 33 becomes an appropriate velocity with respect to the sound velocity of the acoustic wave in the central region 31.

In the sixth modification of the first embodiment, as illustrated in FIGS. 10A and 10B, the protective film 42 (first additional film) is provided on the electrode fingers 22 in the central region 31. The protective film 44 (second additional film) having a sound velocity faster than the sound velocity of the protective film 42 is provided on the electrode fingers 22 in the edge region 33. This also makes it possible to make the third weight in the edge region 33 smaller than the first weight in the central region 31.

In addition, in the first embodiment, as illustrated in FIG. 1A, the additional film 40 is provided on the electrode fingers 22 in the intermediate region 32, and is not provided in the central region 31 and the edge region 33. By providing the additional film 40, the second weight in the intermediate region 32 becomes larger than the first weight in the central region 31. Therefore, the sound velocity of the acoustic wave in the intermediate region 32 becomes slower than the sound velocity of the acoustic wave in the central region 31, and the piston mode can be realized. The additional film 40 may be provided in the band shape in the X direction in the intermediate region 32 as illustrated in FIG. 1A, or may be provided in the dot shape on the electrode fingers 22 in the intermediate region 32 as illustrated in FIG. 9B.

In the fourth modification of the first embodiment, as illustrated in FIG. 9A, the plurality of electrode fingers 22 include electrode fingers 22 each having the width W2 in the intermediate region 32 larger than the width W1 in the central region 31. In such electrode fingers 22, the second weight in the intermediate region 32 is larger than the first weight in the central region 31. Therefore, the sound velocity of the acoustic wave in the intermediate region 32 is slower than the sound velocity of the acoustic wave in the central region 31, and the piston mode can be realized.

The sound velocity of the acoustic wave in the intermediate region 32 may be made slower than that of the acoustic wave in the central region 31 by both providing the additional film 40 on the electrode fingers 22 in the intermediate region 32 and increasing the width of the electrode fingers 22 in the intermediate region 32.

### Second Embodiment

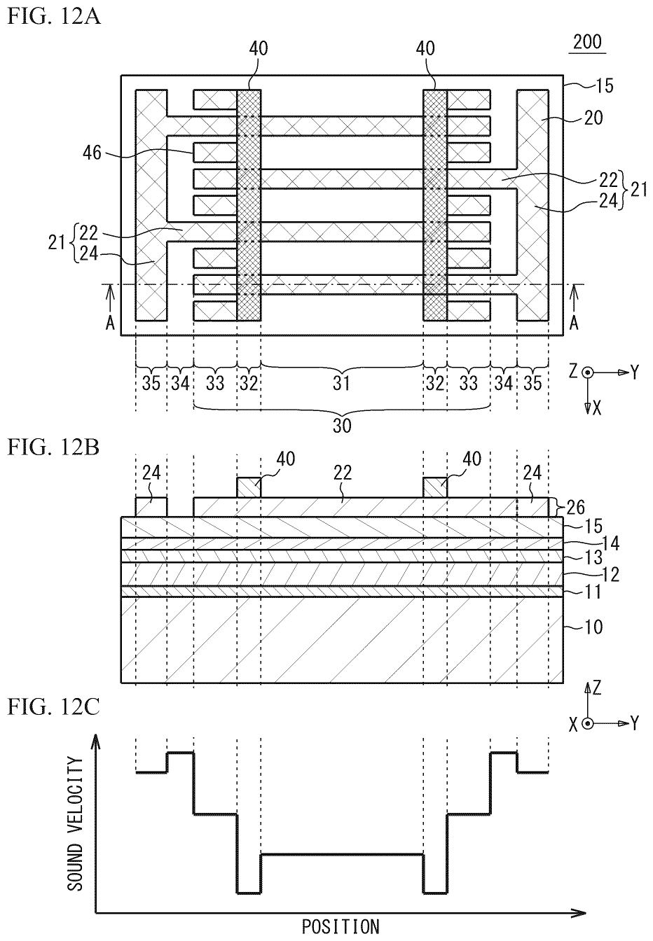

FIG. 12A is a plan view of an acoustic wave device 200 according to a second embodiment. FIG. 12B is a cross-sectional view taken along a line A-A in FIG. 12A. As illustrated in FIGS. 12A and 12B, in the second embodiment, the width and the height of the electrode fingers 22 are constant from one end connected to the bus bar 24 to the other end which is a tip of the opposite side. Isolated electrical conductors 46 alternately arranged in the Y direction with the electrode fingers 22 on the piezoelectric layer 15 in the edge region 33. The isolated electrical conductor 46 is formed of the same material as the electrode finger 22, and has the same width and the same height as the electrode finger 22. The other components are the same as those of the first embodiment, and therefore, the description thereof is omitted.

FIG. 12C is a diagram illustrating the sound velocity of an acoustic wave in the second embodiment. As illustrated in FIG. 12C, since the isolated electrical conductors 46 are provided in the edge region 33, so that the sound velocity of the acoustic wave propagating in the edge region 33 is faster than the sound velocity of the acoustic wave propagating in the central region 31, as in FIG. 3B of the first embodiment. The other components are the same as those in FIG. 3B, and therefore, the description thereof is omitted. The reason why the acoustic velocity of the acoustic wave is increased by providing the isolated electrical conductors 46 is that the reflectance of the acoustic wave in the electrode is reduced.

Also in the second embodiment, the sound velocity (first sound velocity) of the acoustic wave propagating through the intermediate region 32 is slower than the sound velocity (second sound velocity) of the acoustic wave propagating through the central region 31, and the sound velocity (third sound velocity) of the acoustic wave propagating through the edge region 33 is faster than the sound velocity (second sound velocity) of the acoustic wave propagating through the central region 31. Thus, the intermediate region 32 is the low sound velocity region where the sound velocity of the acoustic wave is lower than that of the central region 31, and the edge region 33 is the high sound velocity region where the sound velocity of the acoustic wave is higher than that of the central region 31, so that the piston mode can be realized. Further, since the sound velocity of the acoustic wave in the edge region 33 can be adjusted by the width and the height of the isolated electrical conductor 46, the sound velocity of the acoustic wave in the edge region 33 can be set to be an appropriate velocity with respect to the sound velocity of the acoustic wave in the central region 31. Therefore, the length of the intermediate region 32 in the Y direction can be suppressed from increasing, and thus the size of the device can be suppressed from increasing.

The sound velocity of the acoustic wave in the edge region 33 may be adjusted by adjusting the width and/or the height of the electrode fingers 22 in the edge region 33 in addition to providing the isolated electrical conductors 46 in the edge region 33.

In the first embodiment, the modifications thereof and the second embodiment, the electrode fingers 22 include a metal layer containing W, Mo, Ru, Pt, Ir, Re, Rh or Ta as a main component. In this case, in the configuration of the comparative example illustrated in FIGS. 2A and 2B, the difference in sound velocity between the central region 31 and the high sound velocity region (the edge region 33 in the comparative example) is likely to be large. Accordingly, in this case, it is preferable to adopt the configurations of the first embodiment, the modifications thereof, and the second embodiment.

### Third Embodiment

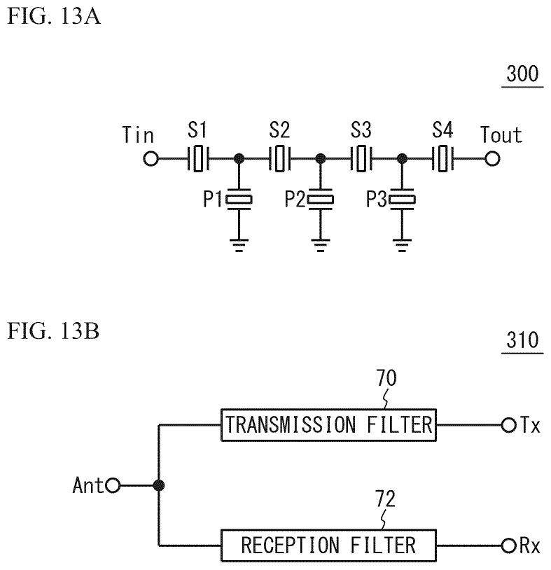

FIG. 13A is a circuit diagram of a filter 300 according to a third embodiment. As illustrated in FIG. 13A, one or a plurality of series resonators S1 to S4 are connected in series between an input terminal Tin and an output terminal Tout. One or a plurality of parallel resonators P1 to P3 are connected in parallel between the input terminal Tin and the output terminal Tout. The acoustic wave device of the first embodiment, the modifications thereof, and the second embodiment can be used for at least one of the series resonators S1 to S4 and the parallel resonators P1 to P3. The number of series resonators and parallel resonators can be set as appropriate. Although the ladder type filter is illustrated as an example of the filter, the filter may be a multi-mode type filter.

FIG. 13B is a circuit diagram of a duplexer 310 according to a modification of the third embodiment. As illustrated in FIG. 13B, a transmission filter 70 is connected between a common terminal Ant and a transmission terminal Tx. A reception filter 72 is connected between the common terminal Ant and a reception terminal Rx. The transmission filter 70 passes a signal in a transmission band of the high frequency signals inputted from the transmission terminal Tx to the common terminal Ant as a transmission signal, and suppresses signals with other frequencies. The reception filter 72 passes a signal in a reception band of the high frequency signals input from the common terminal Ant to the reception terminal Rx as a reception signal, and suppresses signals with other frequencies. At least one of the transmission filter 70 and the reception filter 72 may be the filter of the third embodiment. Although a duplexer is illustrated as an example of the multiplexer, a triplexer or a quadplexer may be used.

Although the embodiments of the present disclosure have been described in detail, it is to be understood that the various change, substitutions, and alterations could be made hereto without departing from the spirit and scope of the invention.

What is claimed is:

1. An acoustic wave device comprising:
a piezoelectric layer; and
a pair of interdigital electrodes provided on the piezoelectric layer, each of the pair of interdigital electrodes having a plurality of electrode fingers and a bus bar to which the plurality of electrode fingers are connected, an intersection region where the plurality of electrode fingers intersect each other including an edge region located at an edge in a longitudinal direction of the plurality of electrode fingers, a central region located inside the edge region, and an intermediate region located between the edge region and the central region;
wherein, when a weight per unit length in the longitudinal direction of a single-layer or multilayer film including a metal layer of at least one of the plurality of electrode fingers provided on the piezoelectric layer at a location where the at least one of the plurality of electrode fingers is located is a first weight in the central region, a second weight in the intermediate region, and a third weight in the edge region, the second weight is larger than the first weight and the third weight is smaller than the first weight.

2. The acoustic wave device according to claim 1, wherein
the second weight is more than 1.0 times and less than 2 times the first weight, and
the third weight is 0.5 times or more and less than 1.0 times the first weight.

3. The acoustic wave device according to claim 1, wherein
a length of the edge region in the longitudinal direction is three times or less of an average pitch of the plurality of electrode fingers of the pair of interdigital electrodes.

4. The acoustic wave device according to claim 1, wherein
the at least one of the plurality of electrode fingers has a width in the edge region smaller than a width in the central region.

5. The acoustic wave device according to claim 1, wherein
the at least one of the plurality of electrode fingers has a height in the edge region smaller than a height in the central region.

6. The acoustic wave device according to claim 1, further comprising:
a first additional film provided on the at least one of the plurality of electrode fingers in the central region; and
a second additional film that is provided on the at least one of the plurality of electrode fingers in the edge region and has a higher sound velocity than the first additional film.

7. The acoustic wave device according to claim 1, further comprising
an additional film provided on the at least one of the plurality of electrode fingers in the intermediate region, and not provided in the central region and the edge region.

8. The acoustic wave device according to claim 1, wherein
the at least one of the plurality of electrode fingers has a width in the intermediate region larger than a width in the central region.

9. An acoustic wave device comprising:
a piezoelectric layer; and
a pair of interdigital electrodes provided on the piezoelectric layer, each of the pair of interdigital electrodes having a plurality of electrode fingers and a bus bar to which the plurality of electrode fingers are connected, an intersection region where the plurality of electrode fingers intersect each other including an edge region located at an edge in a longitudinal direction of the plurality of electrode fingers, a central region located inside the edge region, and an intermediate region located between the edge region and the central region;
wherein a first sound velocity of an acoustic wave propagating in the intermediate region is slower than a second sound velocity of the acoustic wave propagating in the central region and a third sound velocity of the acoustic wave propagating in the edge region is faster than the second sound velocity.

10. The acoustic wave device according to claim 9, wherein
the third sound velocity is 1.01 times or more and 1.07 times or less the second sound velocity.

11. The acoustic wave device according to claim 9, further comprising
an isolated electrical conductor provided between the plurality of electrode fingers in the edge region.

12. The acoustic wave device according to claim 1, wherein
the plurality of electrode fingers include a metal layer containing tungsten, molybdenum, ruthenium, platinum, iridium, rhenium, rhodium, or tantalum as a main component.

13. The acoustic wave device according to claim 9, wherein
the plurality of electrode fingers include a metal layer containing tungsten, molybdenum, ruthenium, platinum, iridium, rhenium, rhodium, or tantalum as a main component.

14. A filter comprising the acoustic wave device according to claim 1.

15. A filter comprising the acoustic wave device according to claim 9.

16. A multiplexer comprising the filter according to claim 14.

17. A multiplexer comprising the filter according to claim 15.
